(19) United States
(12) Patent Application Publication
(10) Pub. No.: US 2006/0152262 A1
(43) Pub. Date: Jul. 13, 2006

(54) Pulse generators with variable pulse width and sense amplifiers using the same and related methods

(76) Inventor: Jae-Kwan Park, Seoul (KR)

Correspondence Address: MYERS BIGEL SIBLEY & SAJOVEC, PO BOX 37428, RALEIGH, NC, 27627, US

(21) Appl. No.: 11/327,681

(22) Filed: Jan. 6, 2006

(30) Foreign Application Priority Data
Jan. 10, 2005 (KR) 10-2005-0002288

(51) Int. Cl. H03K 3/017

(52) U.S. Cl. 327/172

(57) ABSTRACT

Pulse generators include a delay circuit that is responsive to an input signal. The pulse generators also include an output circuit that is configured to generate an output pulse signal in response to the output of the delay circuit. In these pulse generators, the delay circuit has a variable delay that increases proportional to increases in a power supply voltage. Sense amplifiers that include these pulse generators are also provided.

### CROSS-REFERENCE TO RELATED APPLICATIONS

This application claims priority under 35 U.S.C. § 119 from Korean Patent Application No. 2005-2288 filed on Jan. 10, 2005, the disclosure of which is herein incorporated by reference in its entirety.

### FIELD OF THE INVENTION

The present invention relates to semiconductor devices and, more particularly, to pulse generators that may be used, for example, in sense amplifiers, and related methods.

### BACKGROUND OF THE INVENTION

FIG. 1 is a circuit diagram of a conventional sense amplifier. As shown in FIG. 1, the conventional sense amplifier 100 includes a sensing unit 110 and a sense reference unit 120. The sensing unit 110 receives data (e.g., logic 0 or logic 1) of a main cell from a column multiplexer (MUX) 130 through an input terminal VBLM. In response to this input data, the sensing unit 110 outputs a voltage change through an output terminal SOM. The sensing unit 110 precharges the output terminal SOM to a predetermined voltage before receiving the input data. When the sensing unit 110 receives the data of the main cell, the voltage of the output terminal SOM is changed based on the value of the data, and the sensing unit 110 outputs the changed voltage to the sense reference unit 120. The sense reference unit 120 compares the output of the sensing unit 110 with a reference current, and outputs the comparison result to an output terminal /SAOUT.

As is apparent from FIG. 1, when the data received from the main cell has a logic 0 value (inactive data), the voltage of the output terminal SOM increases from the predetermined voltage to which it was precharged. As a result, relatively less current flows through the input transistor P2 of the sense reference unit 120, and the output terminal /SAOUT of the sense reference unit 120 is set to an inactive state. Then, a buffer 140 receives the inactive state to output an active state as the final output by inverting the received inactive state. When the sensing unit 110 receives data from the main cell having a logic value of 1 (active data), the voltage of the output terminal SOM of the sensing unit 110 decreases from the predetermined voltage to which the output terminal SOM was precharged. In response, the current flowing through the input transistor P2 of the sense reference unit 120 increases and the output terminal /SAOUT is set to be in an active state. The buffer 140 then outputs an inactive state as the final output by inverting the received active state.

The operation of the conventional sense amplifier 100 will now be described in more detail, focusing on the voltages of the respective nodes.

Before reading the data received from the main cell, the sensing unit 110 discharges the input terminal VBLM to a ground voltage through a ground terminal VSS. When the sensing unit 110 receives data from the main cell, a current is applied to the input terminal VBLM through PMOS transistor P3 and NMOS transistor N4. Consequently, the voltage of the input terminal VBLM increases. As the input terminal VBLM increases towards a predetermined voltage, the voltage difference between the first intermediate node Vo1 and the input terminal VBLM decreases due to NMOS transistor N6. Eventually, this decrease in the voltage at the first intermediate node Vo1 turns off NMOS transistor N4, halting the precharging of the input terminal VBLM through the PMOS transistor P3 and the NMOS transistor N4. Next, a current is applied to the input terminal VBLM through PMOS transistor P1 and NMOS transistor N1. In response, the voltage of the input terminal VBLM either increases or decreases according to the data received from the main cell. If the data of the main cell is inactive (logic 0), the voltage of the input terminal VBLM increases, but the voltage of a second intermediate node Vo2 decreases. Therefore, a resistance of the NMOS transistor N1 increases and the voltage of the output terminal SOM increases. Consequently, the voltage increases from a power supply voltage VDD to as much as the threshold voltage of the PMOS transistor P1. The sense reference unit 120 mirrors a reference current supplied by PMOS transistor P6 and makes the reference current flow through PMOS transistor P5 and NMOS transistor N3. In addition, the reference current flows through NMOS transistor N2 by a mirror structure comprising NMOS transistors N2 and N3. At this time, a current smaller than the reference current flows through the PMOS transistor P2, which has a gate electrode receiving the voltage of the output terminal SOM of the sensing unit 110. Therefore, the voltage of the output terminal /SAOUT decreases and then becomes inactive.

In contrast, when the data of the main cell is active (logic 1), the voltage of the input terminal VBLM of the sensing unit 110 decreases, and therefore the voltage of the output terminal SOM also decreases. Accordingly, a current larger than the reference current can flow through the PMOS transistor P2, so that the voltage of the output terminal /SAOUT of the sense reference unit 120 increases and an active state is output.

In the conventional sense amplifier 100, the minimum power supply voltage for normal operation of the amplifier is given by following Equations (1) and (2).
Vdd>V(VBLM)+Vth(N4)+Vth(N5)+Vdsat(P4) [Equation 1]
Vdd>V(VBLM)+Vdsat(N1)+Vth(P1) [Equation 2]
where Vdd represents the power supply voltage, V(VBLM) represents the voltage of the input terminal VBLM, Vth represents the threshold voltage of the specified transistor, and Vdsat represents the drain saturation voltage of the specified transistor (i.e., the voltage between drain and source electrodes of the transistor in the operating state).

Assuming threshold voltages of about 0.4 V, drain saturation voltages of about 0.15 V, and the minimum voltage of the input terminal VBLM for reading the data of the main cell to be about 0.4 V, the power supply voltage Vdd becomes about 1.35 V and about 0.95 V respectively in Equations (1) and (2). It can be seen from Equation (1) that when the power supply voltage is smaller than about 1.35 V, normal operation is impossible. Accordingly, if the power supply voltage is smaller than about 1 V, other methods are required.

FIG. 2 is a circuit diagram illustrating a conventional sense amplifier 200 that may be used with lower power supply voltages. As shown in FIG. 2, the conventional sense amplifier 200 includes an address input buffer 210, a read signal input buffer 220, an address transition delay summation circuit 230, a first pulse generator 240, a second pulse generator 250, a sensing unit 260, and a sense reference unit 270.

Unlike the conventional sense amplifier illustrated in FIG. 1, control signals for the sensing unit 260 are not internal voltages, but external control signals ATD1 and ATD2b, so that there are no limits to the voltages. In particular, a first address transition detecting signal ATD1 and a second address transition detecting signal ATD2 are generated by using a first address input signal ADDR and a read input signal RD, and the sensing unit 260 receives data of the main cell by using the first address transition detecting signal ATD1 and an inverted signal ATD2b of the second address transition detecting signal ATD2 as the control signals.

FIG. 3 is a timing diagram illustrating the signals used in the conventional sense amplifier 200 illustrated in FIG. 2. FIG. 4 is a waveform diagram illustrating the signals at the SOR and SOM nodes of the conventional sense amplifier 200.

The operation of the conventional sense amplifier 200 will be described below with reference to FIGS. 2 through 4. When a read input signal RD or an address input signal ADDR is received during a read operation, the address transition delay summation circuit 230 outputs an address transition signal with a delay time to the first pulse generator 240. The first pulse generator 240 outputs the first address transition detecting signal ATD1. The first address transition detecting signal ATD1 is a pulse wave with a predetermined width. The second pulse generator 250 receives the first address transition detecting signal ATD1, and outputs the inverted signal ATD2b of the second address transition detecting signal ATD2. The second address transition detecting signal ATD2 is also a pulse wave having pulses of a predetermined width. The relationship and the pulse widths of these signals are illustrated in FIG. 3.

In the sensing unit 260, an NMOS transistor N1 discharges the output terminal SOM to the ground voltage according to the first address transition detecting signal ATD1, and a PMOS transistor P3 precharges the output terminal SOM according to the inverted second address transition detecting signal ATD2b (refer to time period A or B in FIG. 4). Then, the voltage of the output terminal SOM is rapidly increased, or is maintained, according to the data of the main cell, and the output signal of the sense reference unit 270 becomes active or inactive according to the output signal voltage (the voltage of output terminal SOM) of the sensing unit 260. Since the operation of the sense reference unit 270 has been described above with reference to FIG. 1, a detailed description thereof will be omitted. In such an operation, the activation section (A or B in FIG. 4) of the inverted second address transition detecting signal ATD2b may be very important. If section A or B is too long, the precharge voltage of the output terminal SOM becomes high, which may interfere with proper sensing of the data of the main cell. On the other hand, if the section A or B is to short, sufficient precharging may not be achieved, which may increase the time required to sense the data of the main cell. Specifically, the activation section of the inverted second address transition detecting signal ATD2b is inversely proportional to the power supply voltage. Therefore, as the power supply voltage increases, it takes a longer time to sense the data of the main cell. As illustrated in FIG. 4, when the power supply voltage increases from about 1.0 V to about 1.4 V, the activation section of the inverted second address transition detecting signal ATD2b is reduced (A→B), and thus, the data sensing time increases (Tvdd).

FIG. 5 is a circuit diagram illustrating a conventional pulse generator, and FIG. 6 is a graph illustrating an output signal of the pulse generator in FIG. 5. In the pulse generator of FIG. 5, the input signal IN is delayed through inverters INV1, INV2 and INV3 and capacitors C1, C2, C3, C4 and C5. The delayed signal and the input signal IN are input to a NOR gate NOR and a signal with a predetermined width is output as the output signal of the pulse generator. In this case, if the power supply voltage VDD increases, the capacitors may be charged more quickly, and thus, the delay time may become shorter. Consequently, the pulse width is reduced (W1→W2 in FIG. 6).

### SUMMARY OF THE INVENTION

Pursuant to certain embodiments of the present invention, pulse generators are provided that include a delay circuit that is responsive to an input signal. The pulse generators also include an output circuit that is configured to generate an output pulse signal in response to the output of the delay circuit. In these pulse generators, the delay circuit has a variable delay that increases proportional to increases in a power supply voltage.

In these pulse generators, the delay circuit may comprise a first inverter that controls the charging and/or discharging of at least one first capacitor. The delay circuit may further include a second inverter that controls the charging and/or discharging of at least one second capacitor. The charge stored in the first capacitor may be the input to the second inverter. The pulse generator may also include a reference current generating circuit that is configured to generate a reference current. The delay circuit may also include a first current mirror that is configured to generate a first mirroring current that mirrors the reference current and charges the at least one first capacitor. The pulse generator may also include a second current mirror that is configured to generate a second mirroring current that mirrors the reference current and discharges the at least one second capacitor.

Pursuant to still further embodiments of the present invention, sense amplifiers are provided that include a variable pulse-width pulse generator that is configured to generate a pulse wave having a pulse width that increases as a power supply voltage that is supplied to the variable pulse-width pulse generator increases. These sense amplifiers further include a sensing circuit that is configured to provide an output signal in response to input data and the pulse wave. The sense amplifiers also include a sense reference unit that is configured to sense the value of the input data in response to the output signal.

The sensing time of these sense amplifiers may be substantially constant for operating voltages in the range of about 1.0 volts to about 1.4 volts. The sense amplifiers may also include a fixed pulse-width pulse generator that generates a second pulse wave, and the sensing circuit may be configured to provide an output signal in response to input data, the pulse wave and the second pulse wave. The sense reference unit may be configured to compare a first current that is generated in response to the output signal with a sense reference current. The sense reference unit may also be configured to generate a second output signal based on this comparison. The sense amplifier may also include a buffer that is configured to output a third output signal that designates the value of the input data in response to the second output signal.

In further embodiments of the present invention, pulse generators are provided that include a reference current generating unit, a charge unit, a discharge unit, and a logic unit. The reference current generating unit may generate a reference current in response to, for example, a reference voltage and a block enable signal. The charge unit may be charged via a first mirroring current, and may generate a first output signal in response to an input signal. The first mirror current may be produced by mirroring the reference voltage. The discharge unit may be used to discharge a second mirroring current, and may generate a second output signal in response to, for example, the first output signal and the reference voltage. The second mirroring current may be produced by mirroring the reference current. The logic unit may generate a third output signal that has a pulse width that is substantially proportional to a power supply voltage in response to the input signal and the second output signal.

In other embodiments, pulse generators are provided that include first through fifth PMOS transistors, first through fifth NMOS transistors, first and second capacitors, an inverter, and a NOR gate. The first PMOS transistor has a gate electrode that receives a block enable signal, a source electrode that is electrically connected to a power supply voltage, and a drain electrode that is electrically connected to a first output terminal. The second PMOS transistor has a source electrode that is electrically connected to the power supply voltage, and gate and drain electrodes that are electrically connected to a first output terminal. The first NMOS transistor has a gate electrode that receives the block enable signal, and a drain electrode that is electrically connected to the first output terminal. The second NMOS transistor has a gate electrode that receives the reference voltage, a drain electrode that is electrically connected to a source electrode of the first NMOS transistor, and a source electrode that is electrically connected to a ground voltage. The third PMOS transistor has a gate electrode that is electrically connected to the first output terminal, and a source electrode that is electrically connected to the power supply voltage. The fourth PMOS transistor has a gate electrode that receives the input signal, a source electrode that is electrically connected to the drain electrode of the third PMOS transistor, and a drain electrode that is electrically connected to a second output terminal. The third NMOS transistor has a gate electrode that receives the input signal, a source electrode that is electrically connected to the ground voltage, and a drain electrode that is electrically connected to the second output terminal. The first capacitor connects the second output terminal to the ground voltage. The fifth PMOS transistor has a gate electrode that is electrically connected to the second output terminal, a source electrode that is electrically connected to the power supply voltage, and a drain electrode that is electrically connected to a third output terminal. The fourth NMOS transistor has a gate electrode that is electrically connected to the second output terminal, and a drain electrode that is electrically connected to third output terminal. The fifth NMOS transistor has a gate electrode that is electrically connected to the reference voltage, a drain electrode that is electrically connected to a source electrode of the fourth NMOS transistor, and a source electrode that is electrically connected to the ground voltage. The second capacitor connects the third output terminal to the ground voltage. The inverter has an input terminal that is electrically connected to the third output terminal. The NOR gate has a first input terminal that is electrically connected to an output terminal of the inverter, and a second input terminal that receives the input signal to generate an output signal.

In still other embodiments of the present invention, pulse generators are provided that include a first current source, a first inverter unit, a second current source, a second inverter unit, and a logic unit. The first current source is electrically connected to a power supply voltage to generate a first reference current. The first inverter unit connects the first current source to a ground voltage, and charges or discharges a first output terminal in response to an input signal, and generates a first output signal with an inverted phase of the input signal. The second current source is electrically connected to the ground voltage to generate a second reference current. The second inverter unit connects the second current source to the power supply voltage and charges or discharges a second output terminal in response to the first output signal to generate a second output signal with an inverted phase of the first output signal. The logic unit generates a third output signal with a pulse width substantially proportional to the power supply voltage in response to the second output signal and the input signal.

In still other embodiments, sense amplifiers are provided that include an address input buffer, a read signal input buffer, an address transition delay summation circuit, a first pulse generator, a second pulse generator, a sensing unit, a sense reference unit, and an output unit. The address input buffer receives an address input signal, and the read signal input buffer receives a read input signal. The address transition delay summation circuit receives an output signal of the address input buffer and an output signal of the read signal input buffer, and outputs an address transition signal. The first pulse generator receives the address transition signal, and outputs a first address transition detecting signal with a fixed pulse width. The second pulse generator receives the first address transition detecting signal and a block enable signal, and outputs an inverted signal of a second address transition detecting signal with a pulse width substantially proportional to the power supply voltage. The sensing unit receives data of a main cell through a first input terminal according to the first address transition detecting signal and the inverted signal of the second address transition detecting signal, and outputs a first output signal through a first output terminal. The sense reference unit compares the first output signal with a sense reference current, and outputs a second output signal through a second output terminal. The buffer unit receives the second output signal, and outputs a third output signal. The sense amplifier according to embodiments of the present invention may have a constant sensing time for a wide range of the power supply voltages.

### BRIEF DESCRIPTION OF THE DRAWINGS

FIG. 1 is a circuit diagram illustrating a conventional sense amplifier;

FIG. 2 is a circuit diagram illustrating a conventional sense amplifier that may operate with low power supply voltages;

FIG. 3 is a timing diagram illustrating signals used in the conventional sense amplifier illustrated in FIG. 2;

FIG. 4 is a wave diagram illustrating signals at the SOR and SOM nodes of the conventional sense amplifier illustrated in FIG. 2;

FIG. 5 is a circuit diagram illustrating a conventional pulse generator;

FIG. 6 is a graph illustrating an output signal of the pulse generator in FIG. 5;

FIG. 7 is a circuit diagram illustrating pulse generators according to embodiments of the present invention;

FIG. 8 is a graph illustrating an output signal of the pulse generators in FIG. 7;

FIG. 9 is a circuit diagram illustrating sense amplifiers according to embodiments of the present invention; and

FIG. 10 is a graph illustrating a voltage changes with respect to time at each node of the sense amplifiers illustrated in FIG. 9.

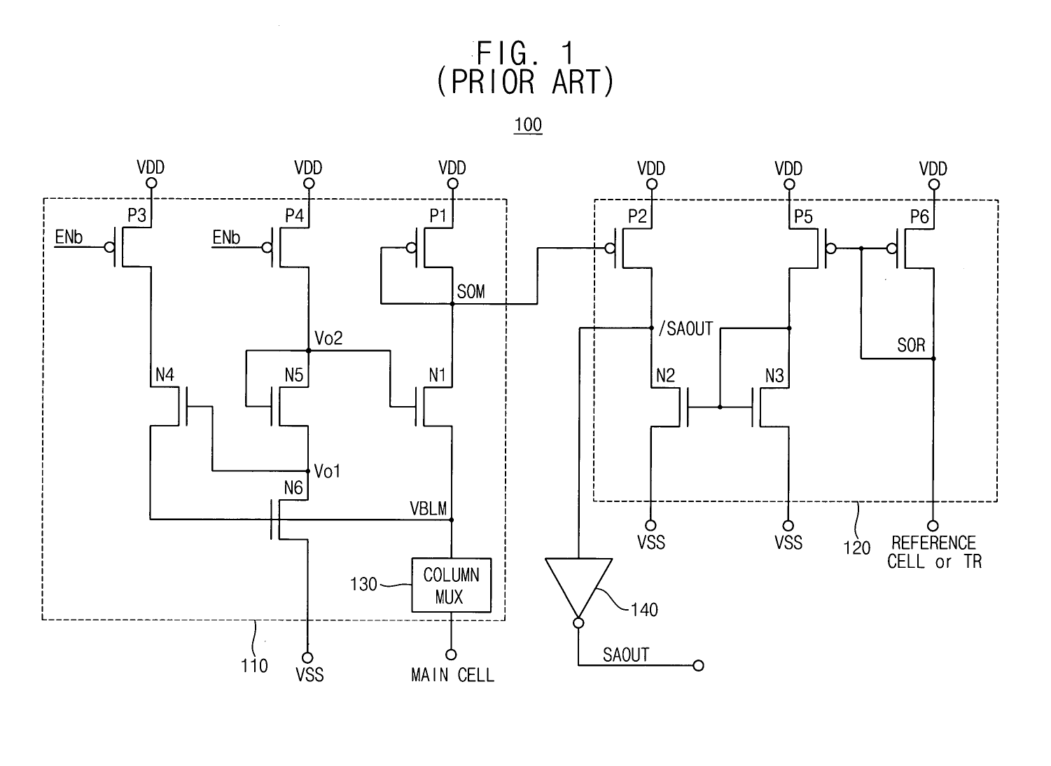

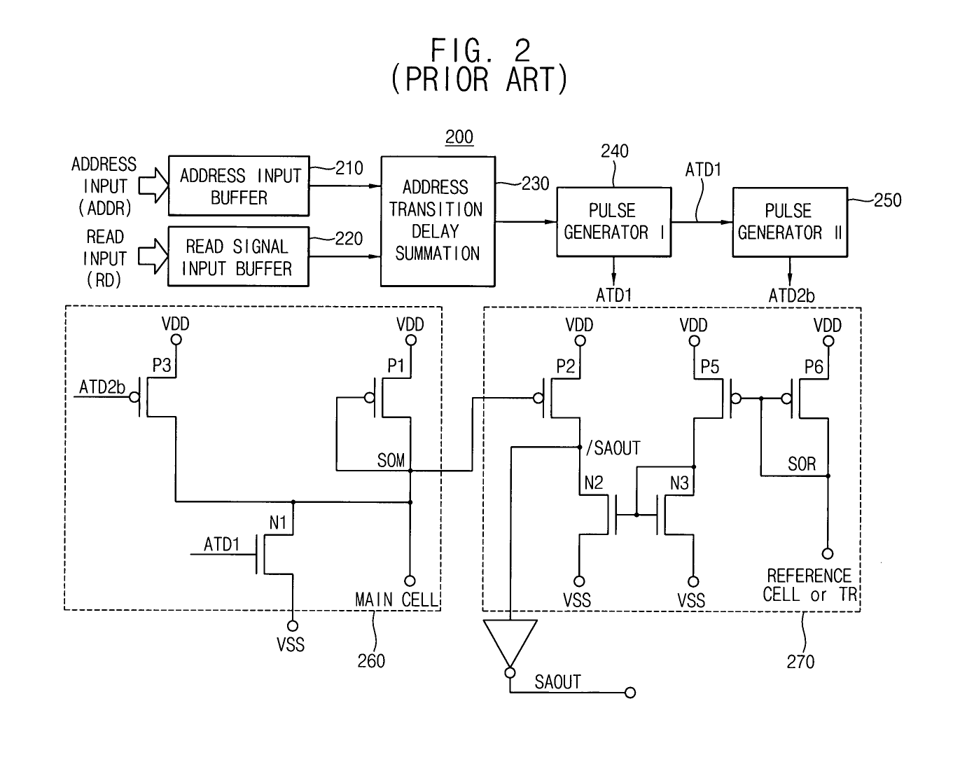

### DETAILED DESCRIPTION

Hereinafter, exemplary embodiments of the present invention will be described in detail with reference to the accompanying drawings.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “electrically connected” or “coupled” to another element, it can be directly electrically connected or coupled to the other element or intervening elements may be present. In contrast, when an element is referred to as being “directly electrically connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

As discussed above, sensing technologies for sensing the data in a memory cell are available that are designed to operate at conventional operating voltages. Sensing technologies have also been developed that are designed for operation at lower operating voltages such as, for example, operating voltages of 1 V or less. However, the sensing technologies that are optimized for these low operating voltages typically may not operate optimally if conventional high operating voltages are applied. Pursuant to embodiments of the present invention, sense amplifiers are provided that include pulse generators having a variable pulse width. These sense amplifiers may be suitable for operation over a range of operating voltages, including low operating voltages such as voltages of 1 V or less.

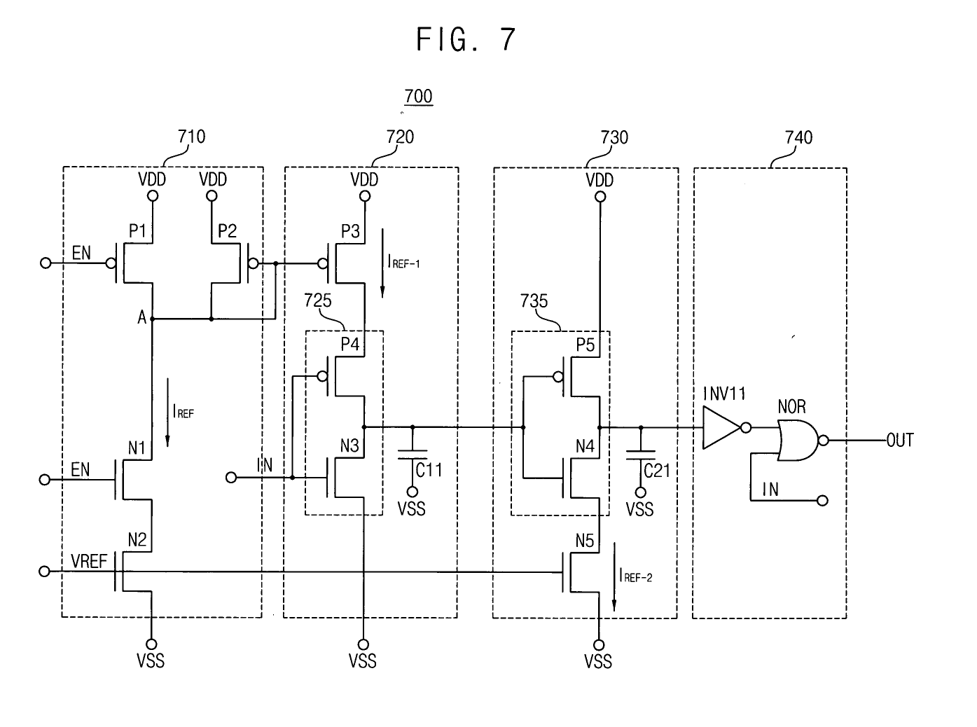

FIG. 7 is a circuit diagram illustrating a pulse generator according to first embodiments of the present invention. As shown in FIG. 7, the pulse generator includes a reference current generating unit 710, a charge unit 720, a discharge unit 730, and a logic unit 740.

The reference current generating unit 710 generates a reference current I_{REF} in response to a block enable signal EN. The reference current generating unit 710 includes transistors P1, P2, N1 and N2. When the block enable signal EN is inactive, the first PMOS transistor P1 is turned on and an intermediate node A is charged to a power supply voltage VDD, thereby turning off the second PMOS transistor P2. In addition, a first NMOS transistor N1 is turned off when the block enable signal EN is inactive, so that no current flows through first NMOS transistor N1. When the block enable signal EN becomes active, the first PMOS transistor P1 is turned off and the first NMOS transistor N1 is turned on, so that a current flows. Due to the reference voltage VREF, the reference current I_{REF} flows through the second PMOS transistor P2, the first NMOS transistor N1, and the second NMOS transistor N2.

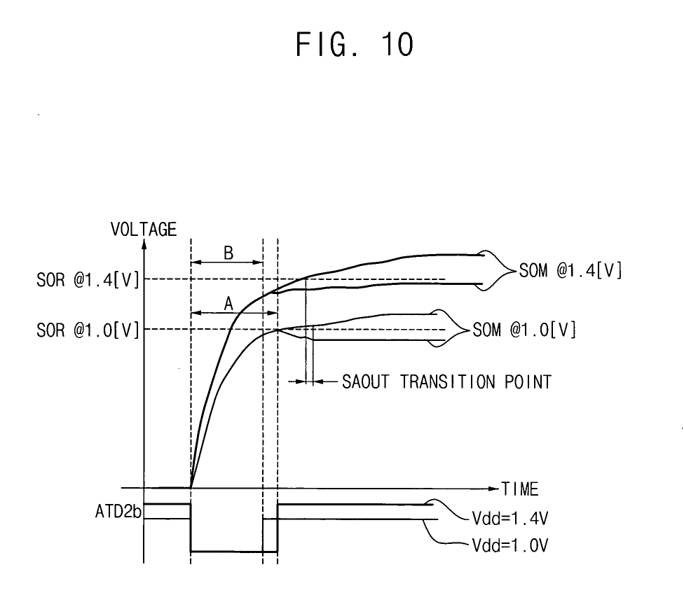

The charge unit 720 includes a third PMOS transistor P3 that is configured to generate a first mirroring current IREF-1, and a first inverter 725 and a first capacitor C11 that are configured to invert an input signal IN. The first inverter unit 725 of the charge unit 720 charges or discharges the first capacitor C11 according to the input signal IN. The input signal IN represents the first address transition detecting signal ATD1 in FIG. 9. When the input signal IN is in an active state, a third NMOS transistor N3 is turned on to discharge the first capacitor C11 to a ground voltage VSS. On the other hand, when the input signal IN is in an inactive state, the first capacitor C11 is charged through a fourth PMOS transistor P4. At this time, because a gate electrode of the third PMOS transistor P3 is electrically connected to the intermediate node A in reference current generating unit 710, the first mirroring current I_{REF-1} produced by mirroring the reference current I_{REF} is supplied to the fourth PMOS transistor P4.

The discharge unit 730 includes a fifth NMOS transistor N5 that is configured to generate a second mirroring current I_{REF-2}, and a second inverter 735 and a second capacitor C21 that are configured to invert an output signal of the charge unit 720. The discharge unit 730 charges or discharges the second capacitor C21 in response to the output signal of the charge unit 720. In particular, when the first capacitor C11 is in an inactive (uncharged) state, a fifth PMOS transistor P5 is turned on so that the second capacitor C21 is charged to the power supply voltage VDD. When the first capacitor C11 is in an active (charged) state, the second capacitor C21 is discharged through a fourth NMOS transistor N4. At this time, the fifth NMOS transistor N5, which has a gate electrode that is electrically connected to the reference voltage, supplies the fourth NMOS transistor N4 with a second mirroring current I_{REF-2} produced by mirroring the reference current I_{REF}.

The logic unit 740 receives the output signal of the second capacitor C21 and the input signal IN, and generates a pulse signal OUT with a pulse width that is substantially proportional to the power supply voltage VDD. The pulse signal OUT represents a second address transition detecting signal ATD2 in FIG. 9.

The delay time from the reception of the input signal IN to the generation of the pulse signal OUT is given by Equation (3) below.
Td(DelayTime)=(Cap1*delta_{—}VA)/I_{REF-1}+(Cap2*delta_{—}VB)/I_{REF-2} [Equation 3]

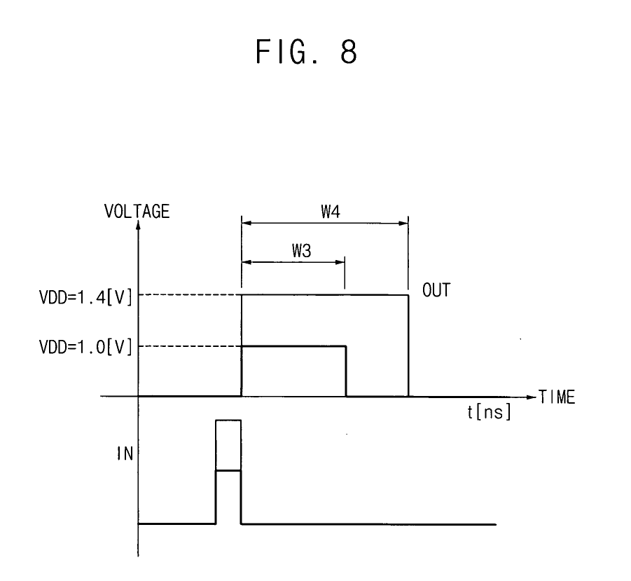

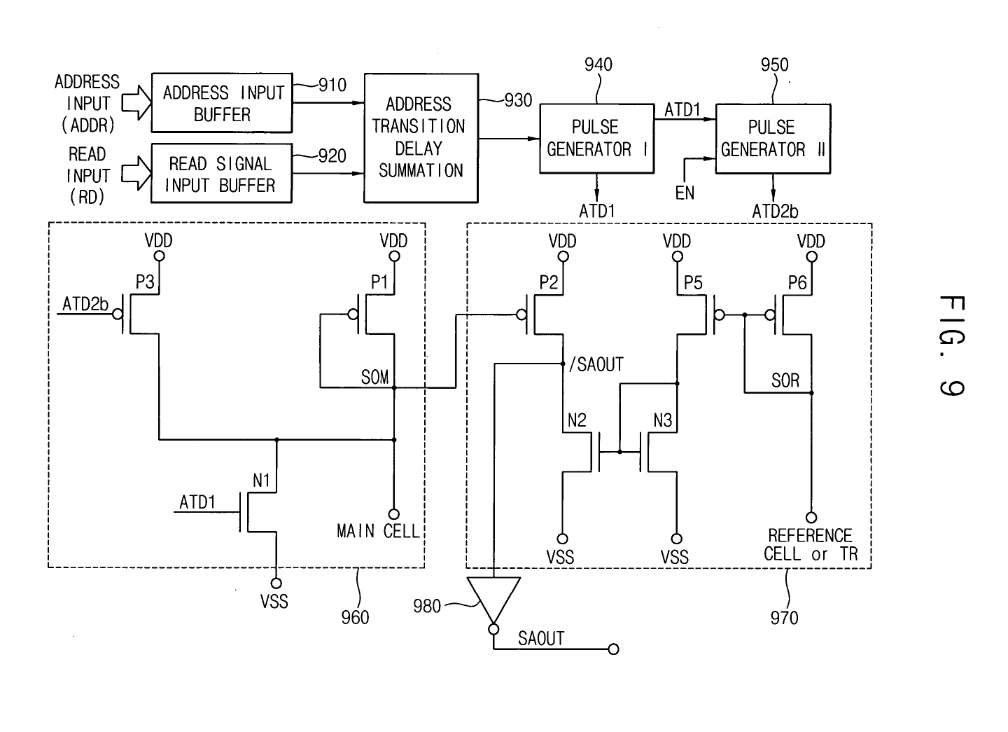

As shown in Equation 3, the delay time at the charge unit 720 is proportional to a capacitance Cap1 of the first capacitor C11 and a first logic threshold voltage delta_VA for driving the second inverter 735, and is inversely proportional to the first mirroring current I_{REF-1}. The first logic threshold voltage delta_VA is the input voltage that triggers a change in the logic level of the output signal of the second inverter 735. Accordingly, when the power supply voltage Vdd increases, the first logic threshold voltage increases in proportion to the power supply voltage Vdd. Consequently, the delay time increases. The delay time at the discharge unit 730 is proportional to the capacitance Cap2 of the second capacitor C21 and a second logic threshold voltage delta_VB for driving an inverter INV11. The second logic threshold voltage delta_VB is the input voltage that triggers a change in the logic level of the output signal of the inverter INV11. When the power supply voltage Vdd increases, the second logic threshold voltage delta_VB increases, and thus, the delay time increases. According to Equation (3), when the power supply voltage Vdd increases, the overall delay time TD increases, and thus, the pulse width of the pulse signal OUT increases (W3→W4 in FIG. 8).

FIG. 9 is a circuit diagram illustrating a sense amplifier according to embodiments of the present invention. FIG. 10 is a graph illustrating a voltage change with respect to time at each node of the sense amplifier circuit in FIG. 9.

Referring to FIG. 9, an address transition delay summation circuit 930 receives an output signal of an address input buffer 910 and an output signal of a read signal input buffer 920, and outputs an address transition signal. First and second pulse generators 940 and 950 output, respectively, a first address transition detecting signal ATD1 and an inverted second address transition detecting signal ATD2b in response to the address transition signal. The sense amplifier uses the output signals ATD1 and ATDb2 of the pulse generators 940 and 950 as control signals. That is, the first pulse generator 940 receives the address transition signal and outputs the first address transition detecting signal ADT1 with a fixed pulse width. The second pulse generator 950 receives the first address transition detecting signal ATD1 and a block enable signal EN, and outputs the inverted second address transition detecting signal ATD2b with a pulse width that is substantially proportional to the power supply voltage Vdd. The block enable signal EN may be the same signal as an input signal of a read signal input buffer 920. A sensing unit 960 discharges an output terminal SOM to a ground voltage in response to the first address transition detecting signal ATD1, and then precharges the output terminal SOM in response to the inverted second address transition detecting signal ATD2b. At this time, a low section of the inverted second address transition detecting signal ATD2b is substantially proportional to the power supply voltage Vdd. Therefore, if the power supply voltage is high, the output terminal SOM may be precharged for a longer time, and thus, its voltage may increase further. Consequently, because data of a main cell is read at higher voltage, the sensing time decreases.

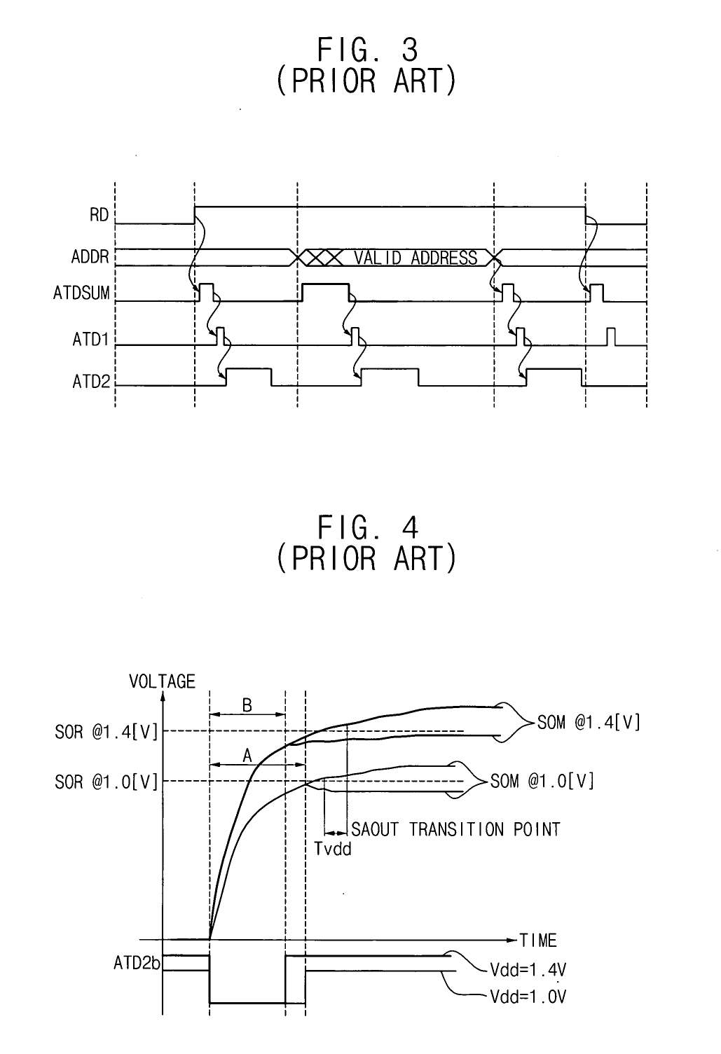

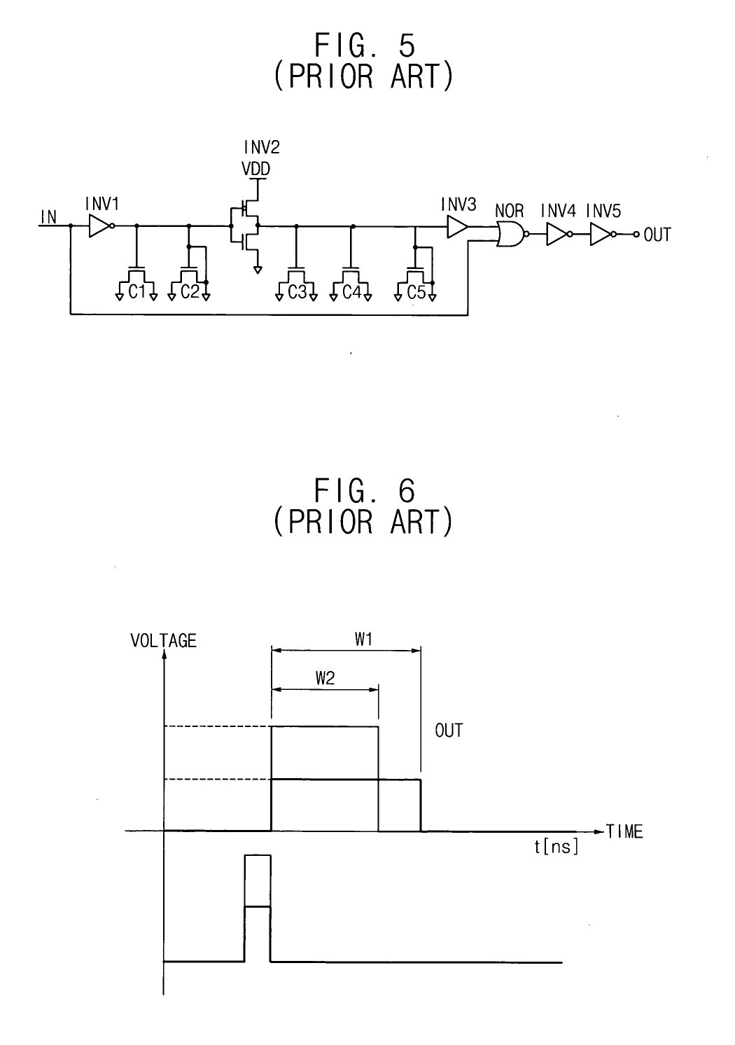

Referring to FIG. 10, unlike the related art (refer to FIG. 3), although the power supply voltage Vdd increases from about 1.0 V to about 1.4 V, there is almost no sensing time delay Tvdd and the sensing is achieved at substantially constant time points. By using the pulse generator that generates the pulse signal with a pulse width that increase according to the increase of the power supply voltage Vdd, the sense amplifier may be implemented, which may have a constant sensing time even when the power supply voltage increases.

As described above, the pulse generators of the present invention may output a pulse wave with a pulse width that is substantially proportional to the power supply voltage. Thus, when the power supply voltage increases, the logic threshold voltage of the inverter increases and the delay time increases. The sense amplifiers of the present invention may have a constant sensing time at a wide range of the power supply voltages by using a pulse wave with a pulse width substantially proportional to the power supply voltage.

While the present invention has been described with respect to the particular embodiments, it will be apparent to those skilled in the art that various changes and modifications may be made without departing from the spirit and scope of the invention as defined in the following claims.

What is claimed is:

1. A pulse generator, comprising:
a delay circuit that is responsive to an input signal; and
an output circuit that is configured to generate an output pulse signal in response to an output of the delay circuit,
wherein the delay circuit has a variable delay that increases proportional to increases in a power supply voltage.

2. The pulse generator of claim 1, wherein the delay circuit comprises a first inverter that controls charging and/or discharging of at least one first capacitor.

3. The pulse generator of claim 2, wherein the delay circuit further comprises a second inverter that controls charging and/or discharging of at least one second capacitor, wherein the charge stored in the first capacitor comprises an input to the second inverter.

4. The pulse generator of claim 3, further comprising:
a reference current generating circuit that is configured to generate a reference current, wherein the delay circuit further comprises a first current mirror that is configured to generate a first mirroring current that mirrors the reference current and charges the at least one first capacitor.

5. The pulse generator of claim 5, further comprising:
a second current mirror that is configured to generate a second mirroring current that mirrors the reference current and discharges the at least one second capacitor.

6. A sense amplifier, comprising:
a variable pulse-width pulse generator that is configured to generate a pulse wave having a pulse width that increases as a power supply voltage that is supplied to the variable pulse-width pulse generator increases;
a sensing circuit that is configured to provide an output signal in response to input data and the pulse wave; and
a sense reference unit that is configured to sense the value of the input data in response to the output signal.

7. The sense amplifier of claim 6, wherein the sensing time of the sense amplifier is substantially constant for operating voltages in the range of about 1.0 volts to about 1.4 volts.

8. The sense amplifier of claim 6, further comprising:
a fixed pulse-width pulse generator that generates a second pulse wave, wherein the sensing circuit that is configured to provide an output signal in response to input data, the pulse wave and the second pulse wave.

9. The sense amplifier of claim 6, wherein the sense reference unit is configured to compare a first current that is generated in response to the output signal with a sense reference current, and is further configured to generate a second output signal based on the comparison.

10. The sense amplifier of claim 9, further comprising:
a buffer that is configured to output a third output signal that designates the value of the input data in response to the second output signal.

11. A pulse generator, comprising:
a reference current generating circuit that is configured to generate a reference current;
a charge circuit that is configured to be charged through a first mirroring current that is produced by mirroring the reference current in response to an input signal;
a discharge circuit that is configured to be discharged through a second mirroring current that is produced by mirroring the reference current in response to an output signal of the charge circuit; and
a logic circuit that is configured to generate a pulsed output signal having a pulse width that is substantially proportional to a power supply voltage in response to the input signal and an output signal of the discharge circuit.

12. The pulse generator of claim 11, wherein the pulsed output signal is in an active state when the input signal is inactive and the output signal of the discharge unit is active.

13. The pulse generator of claim 12, wherein the logic circuit comprises:
an inverter that is responsive to the output signal of the discharge unit; and
a NOR gate that is responsive to the output signal of the inverter and the input signal.

14. A pulse generator comprising:
a first current source electrically connected to a first reference voltage;
a first inverter electrically connecting the first current source and a second reference voltage, the first inverter generating a first output signal;
a second current source electrically connected to the second reference voltage to generate a second reference current;
a second inverter coupled to an output terminal of the first inverter and electrically connecting the second current source and the first reference voltage, the second inverter generating a second output signal; and
a logic circuit that is configured to generate a third output signal with a pulse width that is substantially proportional to the power supply voltage in response to the second output signal and an input signal.

15. The pulse generator of claim 14, wherein the first current source is configured to generate a first reference current, and wherein the first output signal has an inverted phase of an input signal and is generated by charging or discharging the output terminal of the first inverter via the first reference current based on the input signal.

16. The pulse generator of claim 15, wherein the second output signal has a substantially inverted phase of the first output signal and is generated by charging or discharging an output terminal of the second inverter via the second reference current based on the first output signal.

17. The pulse generator of claim 16, wherein the logic circuit outputs the third output signal as an active state when the input signal is inactive and the second output signal is active.

18. The pulse generator of claim 17, wherein, the first inverter comprises:
a first PMOS transistor having a source electrode electrically connected to the first current source, a drain electrode electrically connected to the first output terminal, and a gate electrode electrically connected to the input signal;
a first NMOS transistor having a source electrode electrically connected to the ground voltage, a drain electrode electrically connected to the first output terminal, and a gate electrode electrically connected to the input signal; and
a first capacitor coupled between the first output terminal and the ground voltage.

19. The pulse generator of claim 18, wherein the second inverter comprises:
a second PMOS transistor having a source electrode electrically connected to the power supply voltage, a drain electrode electrically connected to the second output terminal, and a gate electrode electrically connected to the first output terminal;
a second NMOS transistor having a source electrode electrically connected to the second current source, a drain electrode electrically connected to the second output terminal, and a gate electrode electrically connected to the first output terminal; and
a second capacitor coupled between the second output terminal and the ground voltage.

20. A sense amplifier, comprising:
a first pulse generator that is configured to output a first signal;
a second pulse generator that is responsive to the first signal and that is configured to output a second signal having a pulse width that is substantially proportional to the power supply voltage;
a sensing unit that is configured to receive data through a first input terminal in response to the first signal and the second signal and to output a first output signal through a first output terminal;
a sense reference unit that is configured to output a second output signal through a second output terminal in response to a comparison of the first output signal with a sense reference current; and
a buffer that is configured to output a third output signal in response to the second output signal.

21. The sense amplifier of claim 20, further comprising:
an address input buffer that is configured to receive an address input signal;
a read signal input buffer that is configured to receive a read input signal; and
an address transition delay summation circuit that is responsive to an output signal of the address input buffer and an output signal of the read signal input buffer and that is configured to output an address transition signal to the first pulse generator.

22. The sense amplifier of claim 21, wherein the second pulse generator comprises:
a reference current generating circuit that is configured to generate a reference current in response to a reference voltage and a block enable signal;
a charge circuit that is configured to be charged through a first mirroring current and generate a fourth output signal, the first mirroring current being produced by mirroring the reference current in response to the first signal;
a discharge circuit that is configured to be discharged through a second mirroring current and generate a fifth output signal, the second mirroring current being produced by mirroring the reference current in response to the fourth output signal and the reference voltage;
a logic circuit that is configured to generate the second signal in response to the first signal and the fifth output signal.
